(19) United States
(12) Patent Application Publication
(10) Pub. No.: US 2005/0270864 A1
(43) Pub. Date: Dec. 8, 2005

(54) Memory cell arrangement having dual memory cells

(76) Inventor: Peter Poechmueller, Dresden (DE)

Correspondence Address: PATTERSON & SHERIDAN, LLP, 3040 POST OAK BLVD.,, SUITE 1500, HOUSTON, TX, 77056, US

(21) Appl. No.: 11/131,702

(22) Filed: May 18, 2005

(30) Foreign Application Priority Data
May 18, 2004 (DE) DE 102004024552.5

(51) Int. Cl. G11C 7/00

(52) U.S. Cl. 365/200

(57) ABSTRACT

A memory cell arrangement having at least one first and one second memory cell, which respectively have a storage capacitor and a selection transistor, is formed in such a manner that the components in the first memory cell and the components in the second memory cell are arranged in such a manner that they are at least partially nested inside one another in the semiconductor substrate.

### CROSS-REFERENCE TO RELATED APPLICATIONS

This application claims foreign priority benefits under 35 U.S.C. §119 to co-pending German patent application number DE 10 2004 024 552.5, filed 18 May 2004. This related patent application is herein incorporated by reference in its entirety.

### BACKGROUND OF THE INVENTION

1. Field of the Invention

The invention relates to a memory cell arrangement having at least one first memory cell and one second memory cell having respective components that are at least partially nested, and to a memory cell array having a multiplicity of such memory cell arrangements.

2. Description of the Related Art

Dynamic random access memories (DRAMs) predominantly use single-transistor memory cells. A single transistor-transistor memory cell generally comprises a selection transistor and a storage capacitor configured to store information in the form of electrical charges. In this case, a DRAM memory comprises a matrix of single-transistor memory cells, which are connected in the form of rows and columns. The row connections are usually referred to as word lines, and the column connections are usually referred to as bit lines. In this case, the selection transistor and the storage capacitor in the memory cell are connected to one another in such a manner that the storage capacitor's charge can be read in and out using a bit line when the selection transistor is driven using a word line.

The constant trend toward ever more powerful DRAM memories necessitates increasingly higher integration densities for the memory cells. Memory cell concepts using three dimensions are increasingly used to reduce the area required by the memory cells. The storage capacitors are thus increasingly made in the form of trench capacitors beneath the associated selection transistor or in the form of stacked capacitors above the associated selection transistor, resulting in a considerable saving in the chip area needed to form the memory cells. Memory cell concepts in which the selection transistors are also arranged vertically are furthermore known.

However, even the known three-dimensional memory cell arrangements have the disadvantage of requiring a relatively large amount of area to form the memory cell.

Therefore, there is a need for a memory cell arrangement that is distinguished by a reduced area requirement.

### SUMMARY OF THE INVENTION

According to one aspect of the invention, a memory cell arrangement having at least one first and one second memory cell, which respectively have a storage capacitor and a selection transistor, is formed in such a manner that the components in the first memory cell and the components in the second memory cell are at least partially nested inside one another in the semiconductor substrate. In comparison with conventional memory cells, the inventive nested formation of two memory cells at least partially on the same chip area means that a smaller amount of area is needed to form the memory cells, thus, making it possible to miniaturize the DRAM memories further.

In one embodiment, the present invention provides a memory cell arrangement having at least one first and one second memory cell, which respectively has a storage capacitor and a selection transistor. The storage capacitors in the first and second memory cells are, in particular, arranged in such a manner that they are at least partially nested inside one another. Since the storage capacitors, in particular, require a large amount of area on account of the storage capacitance required for reliable charge detection, interleaving the storage capacitors in the two memory cells makes it possible to achieve a densely packed and structurally convenient cell layout with a greatly reduced area requirement.

In one embodiment, the storage capacitors in the first and second memory cells are at least partially formed in a common trench in the semiconductor substrate. Such a cell layout is distinguished by simplified production with a reduced number of trenches for forming the storage capacitors. In addition, this storage capacitor layout makes it possible to achieve a maximum saving in memory cell area.

In one embodiment, the capacitor electrodes of the storage capacitors in the first and second memory cells are arranged in such a manner that they are nested inside one another in the semiconductor substrate in the following order (from the outside inward): outer electrode of a first storage capacitor, inner electrode (which is connected to a first associated selection transistor) of the first storage capacitor, outer electrode of the second storage capacitor and inner electrode (which is connected to a second associated selection transistor) of the second storage capacitor. This arrangement makes it possible for the capacitor electrodes of the two storage capacitors to be arranged in a particularly space-saving manner such that they are nested inside one another and, in addition, permits a simple design within the scope of planar technology.

In another embodiment, on the basis of the nested memory cell arrangement, a memory cell matrix is arranged in such a manner that the two memory cells in each memory cell arrangement are associated with one column and two adjacent rows, with the external capacitor electrodes of the storage capacitors in two adjacent rows respectively being connected to one another. This makes it possible to produce, in a space-saving manner, a common outer electrode in the form of a continuous layer for the respective storage capacitors which are arranged in the common trench. This in turn permits simple and space-saving production.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 schematically shows a circuit diagram of a dynamic memory cell;

FIG. 2 shows a schematic cross section through a memory cell arrangement having two memory cells according to one embodiment of the invention; and

FIG. 3 shows a schematic plan view of a memory cell array having two inventive memory cell arrangements which respectively comprise two memory cells, according to one embodiment of the invention.

### DETAILED DESCRIPTION OF THE PREFERRED EMBODIMENT

Aspects of the invention will be explained with reference to the production of dynamic memory cells in a DRAM memory. In this case, the individual components in the DRAM memory cells may be formed using silicon planar technology that comprises a sequence of individual processes which respectively act on the entire area of the surface of a silicon wafer using suitable masking layers to deliberately change the silicon substrate locally. In this case, a multiplicity of DRAM memory cells are simultaneously formed during production of DRAM memory cells.

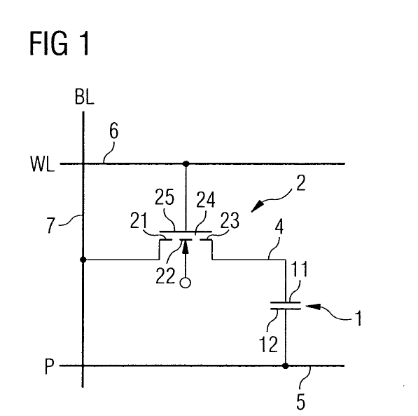

DRAM memories generally use a single-transistor memory cell, the circuit diagram of which is shown in FIG. 1. This single-transistor memory cell comprises a storage capacitor 1 and a selection transistor 2. In this case, the selection transistor 2 is generally in the form of a field effect transistor and has a first source/drain electrode 21 and a second source/drain electrode 23. An active region 22 is arranged between the first source/drain electrode 21 and the second source/drain electrode 23. A gate electrode 25 isolated by a gate insulator layer 24 is arranged above the active region 22. The gate electrode 25 which acts like a plate capacitor is configured to influence the charge density in the active region 22 to form or block a current-conducting channel between the first source/drain electrode 21 and the second source/drain electrode 23.

The second source/drain electrode 23 of the selection transistor 2 is connected to a first capacitor electrode 11 of the storage capacitor 1 via a connecting line 4. A second capacitor electrode 12 of the storage capacitor 1 is in turn connected to a capacitor plate 5 which is common to all of the storage capacitors in the DRAM memory cell array. The first source/drain electrode 21 of the selection transistor 2 is also connected to a bit line 7 configured to enable read-in and read-out the information stored in the storage capacitor 1 in the form of charges. In this case, the read-in and read-out operations are controlled by using a word line 6 that simultaneously forms the gate electrode 25 of the selection transistor 2 to produce a current-conducting channel in the active region 22 between the first source/drain electrode 21 and the second source/drain electrode 23 by applying a voltage.

Three-dimensional structures are generally used as the storage capacitors in DRAM memory cells to reduce the memory cell area. The fundamental implementations of three-dimensional storage capacitors are trench capacitors and stacked capacitors. Trench capacitors comprise a trench which is etched into the semiconductor substrate and then filled with a highly conductive material used as an internal capacitor electrode. By contrast, the external capacitor electrode is formed such that it is buried in the semiconductor substrate and is isolated from the internal capacitor electrode by a dielectric layer. One source/drain electrode of the selection transistor is electrically connected to the internal capacitor electrode via a capacitor connection, e.g., the “buried strap”, which is usually in the form of a diffusion region in the upper trench region. The selection transistor is then generally formed such that it adjoins the trench capacitor in a planar manner on the semiconductor surface, with the source/drain electrodes of the selection transistor in the form of diffusion regions on the semiconductor surface. However, it is also possible to form the selection transistor vertically above the trench capacitor in the trench to save additional memory cell area.

As an alternative, however, the storage capacitor may be arranged in the form of a stacked capacitor above the selection transistor, with the internal capacitor electrode generally the form of a crown and connected to one source/drain electrode of the selection transistor. The external capacitor electrode is then generally a conductive layer isolated from the internal capacitor electrode by a dielectric layer.

To save additional memory cell area and ensure additional miniaturization of the DRAM memories, one embodiment of the invention provides for the DRAM memory cells to be in the form of dual memory cells, with the components, i.e., the selection transistors and/or the storage capacitors, in the two memory cells formed such that they are nested inside one another. In one aspect, the storage capacitors for the two memory cells may be formed such that they are nested inside one another. This may be effected for trench capacitors by arranging the two storage capacitors in a common trench and by forming the capacitor electrodes in the following order (from the outside inward): external capacitor electrode of a first storage capacitor, internal capacitor electrode of the first storage capacitor, external capacitor electrode of a second storage capacitor and internal capacitor electrode of the second storage capacitor. Storage capacitors (in the form of stacked capacitors) in a dual memory cell arrangement may be formed in such a manner that the storage capacitors are arranged such that they are nested inside one another in a common well, with the order of the capacitor electrodes (from the outside inward) corresponding to that for the trench capacitors.

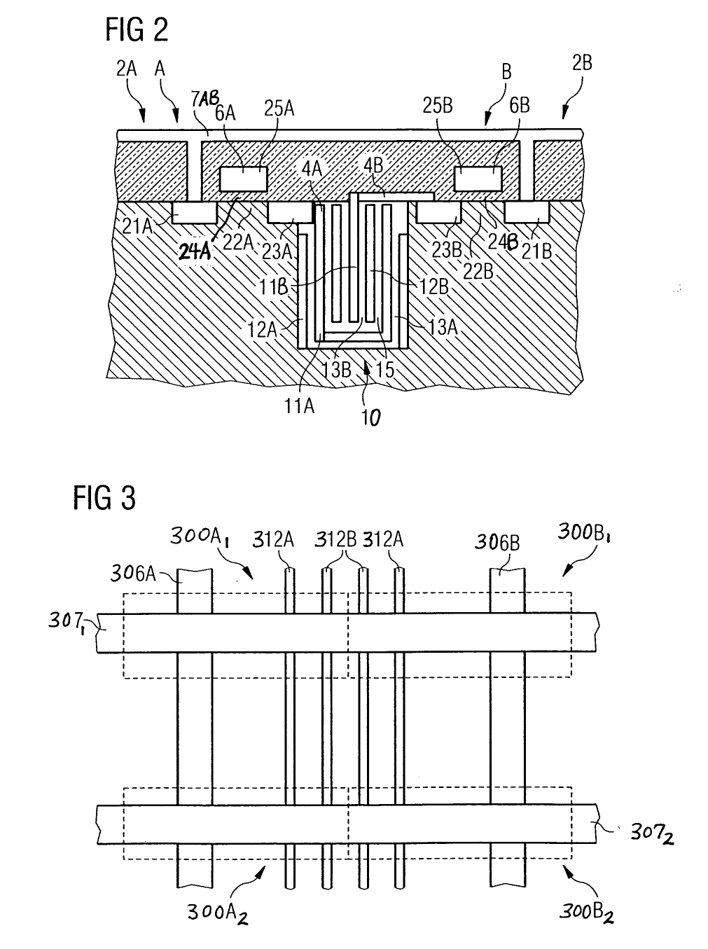

FIG. 2 schematically shows a cross section through a dual memory cell, according to one embodiment of the invention, using the example of a memory cell design having a planar selection transistor and an adjoining trench capacitor. A first memory cell A and a second memory cell B respectively have a selection transistor 2A, 2B. The transistors 2A and 2B are formed in a planar manner such that they adjoin a common trench 10. Each of the two selection transistors 2A, 2B is in the form of a planar field effect transistor and has a first source/drain electrode 21A, 21B, respectively, that delivers current and a second source/drain electrode 23A, 23B, respectively, that receives current. A respective active region 22A, 22B, in which a current-conducting channel can form between the two source/drain electrodes 21A, 21B, and 23A, 23B, is arranged between the source/drain electrodes 21A, 21B and 23A, 23B. A respective gate electrode 25A, 25B is arranged above the active region 22A, 22B in such a manner that it is isolated by an insulator layer 24A, 24B. Each gate electrode 25A, 25B is configured to influence the charge density in the respective active region 22A, 22B. The first source/drain electrode 21A, 21B of the selection transistors 2A, 2B is connected to a common bit line 7AB. Each selection transistor 2A, 2B is controlled using an associated word line 6A, 6B which is respectively connected to the gate electrode 25A, 25B of the selection transistors 2A, 2B and is generally integral with the latter.

Each second source/drain electrode 23A, 23B of the selection transistors 2A, 2B is respectively connected, via a capacitor connection 4A, 4B, to an internal capacitor electrode 11A, 11B of the respectively associated trench capacitor. The internal capacitor electrodes are formed in the common trench 10. As the cross section in FIG. 2 shows, the capacitor electrodes which are associated with the respective memory cell A, B are generally formed in such a manner that an outer electrode 12A of the trench capacitor associated with the memory cell A is in the form of an external layer on the two trench walls. An inner electrode 11A of the first trench capacitor is then isolated from the outer electrode 12A by a dielectric layer 13A that may have a U-shaped cross section in the trench 10. An outer electrode 12B of a second trench capacitor in the second memory cell B is arranged in the trench 10 (in the form of dual plates which are spaced apart) in such a manner that it is again isolated from the internal capacitor electrode 11A by an insulator layer 15. The outer electrode 12B is isolated from a plate-shaped inner electrode 11B of the second trench capacitor in the center of the trench 10 by a further dielectric layer 13B. In this case, the dielectric layer 13A, the insulator layer 15 and the dielectric layer 13B are generally made of the same insulating material. The internal and external capacitor electrodes 11A, 11B, 12A, 12B, are formed from the same conductive material, such as, for example, polysilicon or metal. This nested arrangement of the capacitor electrodes of the trench capacitors associated with the two adjacent memory cells A, B makes it possible to considerably reduce the chip area required by the two memory cells and to miniaturize the memory cell arrangement.

A memory cell array in a DRAM memory comprises bit lines, which may run in vertical rows, and word lines, which may run in horizontal rows. According to one embodiment of the invention, referring to FIG. 3, the DRAM memory cell array is formed in such a manner that the memory cells 300A₁, 300B₁ whose trench capacitors are nested inside one another are connected to the same bit line 307₁ and are respectively associated with one adjacent word line 306A, 306B, respectively. This arrangement is shown in the plan view in FIG. 3, which shows two sets of nested dual memory cells 300A₁/300B₁ and 300A₂/300B₂ (which is connected to bitline 307₂) arranged parallel to one another. In this case, the external capacitor electrodes 312A, 312B (which are respectively in the form of two plates) of the memory cells (300A₁/300B₁ and 300A₂/300B₂), which are arranged parallel to one another, are respectively connected to one another and form a common capacitor plate. Thus, the external capacitor electrodes 312A, 312B of the dual memory cells (300A₁/300B₁ and 300A₂/300B₂) which are arranged parallel to one another can be produced in a simple manner and, in addition, save a considerable amount of space.

As an alternative to the embodiment shown in FIG. 3 having storage capacitors of two adjacent memory cells arranged in such a manner that they are nested inside one another in a common trench, it is possible to arrange stacked capacitors in a similar manner in the form of a crown above the planar selection transistors. In this case too, the external capacitor electrodes of memory cells which are arranged parallel to one another can then be in the form of a common layer.

While the foregoing is directed to embodiments of the present invention, other and further embodiments of the invention may be devised without departing from the basic scope thereof, and the scope thereof is determined by the claims that follow.

1. A memory cell arrangement formed in a semiconductor substrate, comprising:
a first memory cell comprising a first selection transistor and a first storage capacitor; and
a second memory cell comprising a second selection transistor and a second storage capacitor, wherein at least one component of the first memory cell is at least partially nested inside at least one component of the second memory cell in the semiconductor substrate.

2. The memory cell arrangement of claim 1, wherein one of the first storage capacitor in the first memory cell and the second storage capacitor in the second memory cell is at least partially nested inside the other in the semiconductor substrate.

3. The memory cell arrangement of claim 2, wherein the first storage capacitor in the first memory cell and the second storage capacitor in the second memory cell are arranged at least partially in a common trench in the semiconductor substrate.

4. The memory cell arrangement of claim 3, wherein each storage capacitor comprises:
a first capacitor electrode;
a second capacitor electrode; and
a dielectric layer disposed between the first capacitor electrode and the second capacitor electrode.

5. The memory cell arrangement of claim 4, wherein the first storage capacitor is nested inside the second storage capacitor in the common trench in the semiconductor substrate in the following order from outside inward: the second capacitor electrode of the second storage capacitor, the first capacitor electrode of the second storage capacitor, the second capacitor electrode of the first storage capacitor and the first capacitor electrode of the first storage capacitor.

6. The memory cell arrangement of claim 1, wherein the storage capacitors are trench capacitors in the form of dual plates.

7. The memory cell arrangement of claim 6, wherein the storage capacitor in the first memory cell and the storage capacitor in the second memory cell are arranged in a common trench in the semiconductor substrate.

8. A memory device formed on a semiconductor substrate, comprising,
a plurality of dual memory cells arranged in a matrix of rows and columns;
a plurality of bit lines, wherein each of the plurality of the bit lines is associated with a column of the matrix and electrically connected to the memory cells of the corresponding column; and
a plurality of word lines, wherein each of the plurality of the word lines is associated with a row of the matrix and electrically connected to the memory cells of the corresponding row,
wherein each pair of dual memory cells comprises:
a first memory cell comprising a first selection transistor and a first storage capacitor; and
a second memory cell comprising a second selection transistor and a second storage capacitor, wherein at least one component of the first memory cell is at least partially nested inside at least one component of the second memory cell in the semiconductor substrate.

9. The memory device of 8, wherein, for each pair of dual memory cells, one of the first storage capacitor in the first memory cell and the second storage capacitor in the second memory cell is at least partially nested inside the other in the semiconductor substrate.

10. The memory device of claim 9, wherein, for each pair of dual memory cells, the first storage capacitor in the first memory cell and the second storage capacitor in the second memory cell are arranged at least partially in a common trench in the semiconductor substrate.

11. The memory device of claim 10, wherein each storage capacitor comprises:
a first capacitor electrode;
a second capacitor electrode; and
a dielectric layer disposed between the first capacitor electrode and the second capacitor electrode.

12. The memory device of claim 11, wherein, for each pair of dual memory cells, the first storage capacitor is nested inside the second storage capacitor in the common trench in the semiconductor substrate in the following order from outside inward: the second capacitor electrode of the second storage capacitor, the first capacitor electrode of the second storage capacitor, the second capacitor electrode of the first storage capacitor and the first capacitor electrode of the first storage capacitor.

13. The memory device of claim 11, wherein each pair of dual memory cells is respectively associated with two adjacent columns and one row, wherein the second capacitor electrodes of the storage capacitors in adjacent rows are respectively connected.

14. A memory cell arrangement having dual memory cells, comprising:
a first memory cell comprising a first storage capacitor and a first selection transistor; and
a second memory cell comprising a second storage capacitor and a second selection transistor,
wherein each storage capacitor comprises an internal capacitor electrode electrically connected to the corresponding selection transistor and an external capacitor electrode, and
wherein the first storage capacitors is at least partially interleaved with the second storage capacitor.

15. The memory cell arrangement of 14, wherein each selection transistor comprises:
a first source/drain electrode electrically connected to a bit line;
a second source/drain electrode; and
a channel region between the first source/drain electrode and the second source/drain electrode,
wherein the first capacitor electrode is electrically connected to the second source/drain electrode such that a word line configured to drive the channel region enables a connection from the bit line to the first capacitor electrode via the first source/drain electrode, the channel region and the second source/drain electrode.

16. The memory cell arrangement of 15, wherein the first storage capacitor and the second storage capacitor are dual plate trench capacitors disposed in a common trench in a semiconductor substrate.

17. The memory cell arrangement of 16, wherein the first storage capacitor and the second storage capacitor are arranged in the following order from outside inward: the external capacitor electrode of the second storage capacitor, the internal capacitor electrode of the second storage capacitor, the external capacitor electrode of the first storage capacitor and the internal capacitor electrode of the first storage, wherein a dielectric material is disposed between adjacent capacitor electrodes.

18. The memory cell arrangement of claim 15, wherein a plurality of dual memory cells are arranged in a matrix of rows and columns, wherein each column is associated with a bit line of a plurality of the bit lines and each row is associated with a word line of a plurality of word lines.

19. The dual memory cell of 18, wherein, for two adjacent pairs of dual memory cells arranged on adjacent rows, the external capacitor electrodes of the first storage capacitors are connected within the same trench and the external capacitor electrodes of the second storage capacitors are connected within the same trench.

20. The dual memory cell of 19, wherein the external capacitor electrodes of the first storage capacitors and the external capacitor electrodes of the second storage capacitors are arranged in a parallel formation, wherein the external capacitor electrodes of the first storage capacitors are formed in a first common layer and wherein the external capacitor electrodes of the second storage capacitors are formed in a second common layer.
